(19) United States
(12) Patent Application Publication
(10) Pub. No.: US 2026/0082654 A1
(43) Pub. Date: Mar. 19, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Fan Hsuan Chien, Tainan City (TW); Yu-Bi Yu, Hsinchu City (TW); Ming Lun You, Taichung City (TW); Mu-Min Hung, Hsinchu City (TW); Ling-Yu Yang, Tainan (TW); Chen-Tsu Fu, Tainan City (TW)

(73) Assignee: Taiwan Semiconductor Manufacturing Company, Ltd., Hsinchu (TW)

(21) Appl. No.: 18/885,991

(22) Filed: Sep. 16, 2024

(51) Int. Cl. H01L 29/66; H01L 21/02; H01L 29/417

(52) U.S. Cl. CPC H10D 64/018; H10D 64/021; H10D 64/258; H10P 14/6922; H10P 14/69433

(57) ABSTRACT

A fabrication method, includes: forming a gate spacer layer around a sacrificial gate structure disposed over a substrate; performing, on a first material layer that includes the gate spacer layer, treatment operations that are configured to make the first material layer more resistant to Germanium (Ge) diffusion during metal gate replacement operations; forming a second material layer adjacent to the first material layer; and replacing the sacrificial gate structure with a metal gate, wherein the first material layer blocks Ge from entering the metal gate.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart depicting an example method of semiconductor fabrication, in accordance with some embodiments.

FIGS. 2-3, 4A-4C, 5, 6A-6B, and 7-15, are schematic diagrams that illustrate an example semiconductor device structure at various stages of fabrication, in accordance with some embodiments.

FIG. 16 is a flow chart depicting an example method of semiconductor fabrication, in accordance with some embodiments.

FIGS. 17A-17D are schematic diagrams of an example semiconductor device at different stages of fabrication after forming a sacrificial gate, in accordance with some embodiments.

FIG. 18 is a flow chart depicting another example method of semiconductor fabrication, in accordance with some embodiments.

FIGS. 19A-19D are schematic diagrams depicting another example semiconductor device at different stages of fabrication after forming a sacrificial gate, in accordance with some embodiments.

FIG. 20 is a flow chart depicting another example method of semiconductor fabrication, in accordance with some embodiments.

FIGS. 21A-21D are schematic diagrams depicting another example semiconductor device at different stages of fabrication after forming a sacrificial gate, in accordance with some embodiments.

FIGS. 22A and 22B are schematic diagrams of another example semiconductor device at different stages of fabrication, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

It should be understood that, although the terms first, second, third etc. may be used herein to describe various elements, components, regions, layers, portions and/or sections, these elements, components, regions, layers, portions, and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

Various embodiments are discussed herein in a particular context, namely, for forming a semiconductor structure that includes a fin-like field-effect transistor (FinFET) device. The semiconductor structure, for example, may be a complementary metal-oxide-semiconductor (CMOS) device including a P-type metal-oxide-semiconductor (PMOS) FinFET device and an N-type metal-oxide-semiconductor (NMOS) FinFET device. Embodiments will now be described with respect to particular examples including FinFET manufacturing processes. Embodiments, however, are not limited to the examples provided herein, and the ideas may be implemented in a wide array of embodiments. Thus, various embodiments may be applied to other semiconductor devices/processes, such as planar transistors, and the like. Further, embodiments discussed herein are discussed in the context of devices formed using a gate-last process.

While the figures illustrate various embodiments of a semiconductor device, additional features may be added in the semiconductor device depicted in the Figures and some of the features described below can be replaced, modified, or eliminated in other embodiments of the semiconductor device.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

The present disclosure is generally related to semiconductor devices and the fabrication thereof, and in some cases to multi-gate devices. Multi-gate devices include those transistors whose gate structures are formed on at least two-sides of a channel region. These multi-gate devices may include an n-type metal-oxide-semiconductor device or a p-type metal-oxide-semiconductor multi-gate device. Specific examples herein may be presented and referred to herein as a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Presented herein are embodiments of devices that may have one or more channel regions (e.g., nanosheets) associated with a single, contiguous gate structure. However, one of ordinary skill would recognize that the teaching can apply to a single channel or any number of channels, such as a FinFET device, on account of its fin-like structure. One of ordinary skill may recognize other examples of semiconductor devices that may benefit from aspects of the present disclosure.

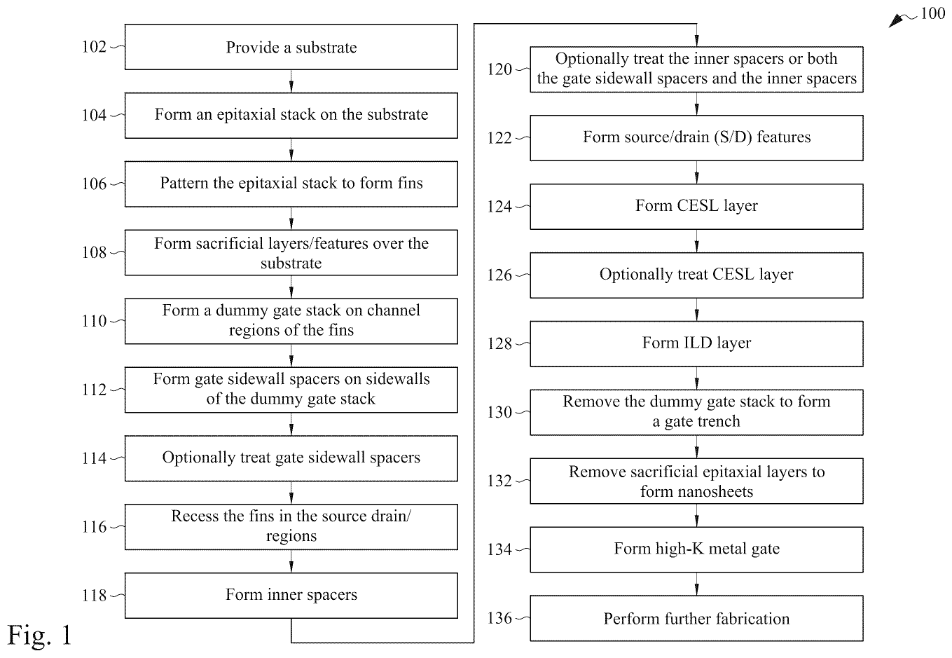

FIG. 1 is a flow chart depicting an example method 100 of semiconductor fabrication including fabrication of multi-gate devices, according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAA device having gate material disposed on four sides of at least one channel member of the device. The channel member may be referred to as “nano structure” or “nanosheet,” which is used herein to designate any material portion with nanoscale, or even microscale dimensions, and having an elongate shape, regardless of the cross-sectional shape of this portion. Thus, the term “nanostructure” or “nanosheet” as used herein designates both circular and substantially circular cross-section elongate material portions, and beam or bar-shaped material portions including for example a cylindrical in shape or substantially rectangular cross-section.

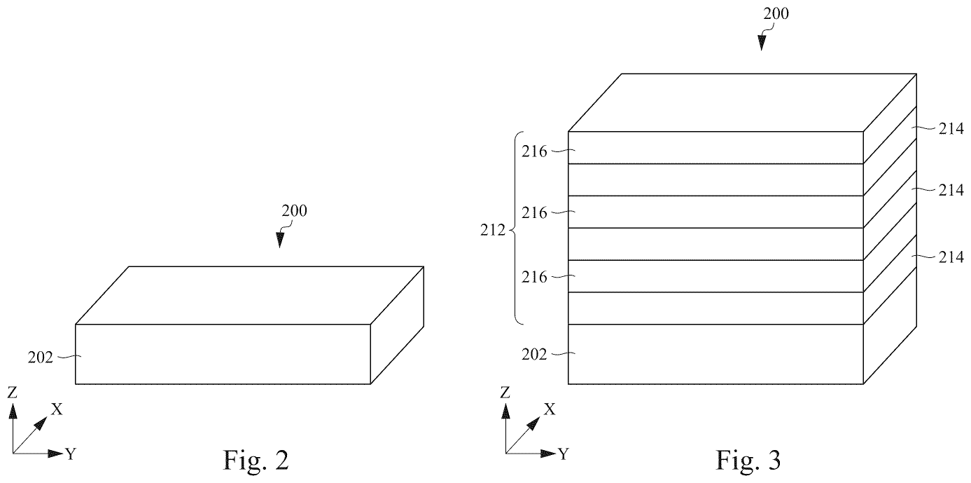

FIG. 1 is described in conjunction with FIGS. 2-3, 4A-4C, 5, 6A-6B, and 7-15, which illustrate a semiconductor device 200 or structure at various stages of fabrication in accordance with some embodiments. The method 100 is merely an example and is not intended to limit the present disclosure beyond what is explicitly recited in the claims. Additional steps may be provided before, during, and after method 100, and some of the steps described can be moved, replaced, or eliminated for additional embodiments of method 100. Additional features may be added in the semiconductor device 200 depicted in the figures, and some of the features described below can be replaced, modified, or eliminated in other embodiments.

As with the other method embodiments and exemplary devices discussed herein, it is understood that parts of the semiconductor devices may be fabricated by semiconductor technology process flow, and thus some processes are only briefly described herein. Further, the exemplary semiconductor devices may include various other devices and features, such as other types of devices such as additional transistors, bipolar junction transistors, resistors, capacitors, inductors, dials, fuses, and/or other logic devices, etc., but is simplified for better understanding of concepts of the present disclosure. In some embodiments, exemplary devices include a plurality of semiconductor devices (e.g., transistors), including PFETs, NFETs, etc., which may be interconnected. Moreover, it is noted that the process steps of method 100, include any descriptions given with reference to the figures, as with the remainder of the method and exemplary figures provided in this disclosure, are merely exemplary and are not intended to be limiting beyond what is specifically recited in the claims that follow.

FIGS. 2-3, 4A-4C, 5, 6A-6B, and 7-15, are schematic diagrams that illustrate an example semiconductor device structure at various stages of fabrication, in accordance with some embodiments. In some figures, some reference numbers of components or features illustrated therein may be omitted to avoid obscuring other components or features; this is for ease of depicting the figures.

At block 102, the example method 100 includes providing a substrate. Referring to the example of FIG. 2, in an embodiment of block 102, a substrate 202 is provided for forming a transistor device 200. In some embodiments, the substrate 202 may be a semiconductor substrate such as a silicon (Si) substrate. In some embodiments, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. The substrate 202 may include various layers, including conductive or insulating layers formed on a semiconductor substrate. The substrate 202 may include various doping configurations depending on design requirements. For example, different doping profiles (e.g., n wells, p wells) may be formed on the substrate 202 in regions designed for different device types (e.g., n-type field effect transistors (NFET), p-type field effect transistors (PFET)). The suitable doping may include ion implantation of dopants and/or diffusion processes. The substrate 202 has isolation features (e.g., shallow trench isolation (STI) features) interposing the regions providing different device types. Further, the substrate 202 may be strained for performance enhancement, may include a silicon-on-insulator (SOI) structure, and/or have other suitable enhancement features.

At block 104, the example method 100 then includes forming an epitaxial stack over the substrate that includes a plurality of epitaxial layers. Referring to the example of FIG. 3, in an embodiment of block 104, an epitaxial stack 212 is formed over the substrate 202. The epitaxial stack 212 includes sacrificial epitaxial layers 214 of a first composition interposed by channel epitaxial layers 216 of a second composition. The first and second composition can be different. In an embodiment, the sacrificial epitaxial layers 214 are formed from SiGe and the channel epitaxial layers 216 are formed from silicon (Si). However, other embodiments are possible including those that provide for a first composition and a second composition having different oxidation rates and/or etch selectivity. In some embodiments, the sacrificial epitaxial layer 214 includes SiGe and the channel epitaxial layer 216 includes silicon (Si). However, other embodiments are possible including those that provide for a first composition and a second composition having different oxidation rates and/or etch selectivity. In some embodiments, the sacrificial epitaxial layer 214 includes SiGe and where the channel epitaxial layer 216 includes Si, the Si oxidation rate of the channel epitaxial layer 216 is less than the SiGe oxidation rate of the sacrificial epitaxial layer 214. It is noted that three (3) layers each of epitaxial layers 214 and 216 are illustrated in FIG. 3, which is for illustrative purposes only and not intended to be limiting beyond what is specifically recited in the claims. In various embodiments, any number of epitaxial layers can be formed in the epitaxial stack 212; the number of layers depending on the desired number of channel regions for the device 200. In some embodiments, the number of channel epitaxial layers 216 is between 2 and 10, such as 3, 4 or 5.

In some embodiments, the sacrificial epitaxial layer 214 has a thickness ranging from about 4 nm to about 12 nm. The sacrificial epitaxial layers 214 may be substantially uniform in thickness. In some embodiments, the channel epitaxial layer 216 has a thickness ranging from about 3 nm to about 6 nm. In some embodiments, the channel epitaxial layers 216 of the stack are substantially uniform in thickness.

As described in more detail below, the channel epitaxial layer 216 may serve as channel region(s) for a subsequently-formed multi-gate device and its thickness is chosen based on device performance considerations. The sacrificial epitaxial layer 214 may serve to reserve a spacing (or referred to as a gap) between adjacent channel region(s) for a subsequently-formed multi-gate device and its thickness is chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers, such as the channel epitaxial layers 216, include the same material as the substrate 202, such as silicon (Si). In some embodiments, the epitaxially grown layers 214 and 216 include a different material than the substrate 202. As stated above, in at least some examples, the sacrificial epitaxial layer 214 includes an epitaxially grown Si₁₋ₓGeₓ layer (e.g., x is about 25^{˜}55%) and the channel epitaxial layer 216 includes an epitaxially grown Si layer. Alternatively, in some embodiments, either of the sacrificial epitaxial layers 214 and channel epitaxial layers 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the sacrificial epitaxial layers 214 and channel epitaxial layers 216 may be chosen based on providing differing oxidation and etch selectivity properties. In various embodiments, the epitaxial layers 214 and 216 are substantially dopant-free (i.e., having an extrinsic dopant concentration from about 0 cm⁻³ to about 1×10¹⁷ cm⁻³), where for example, no intentional doping is performed during the epitaxial growth process.

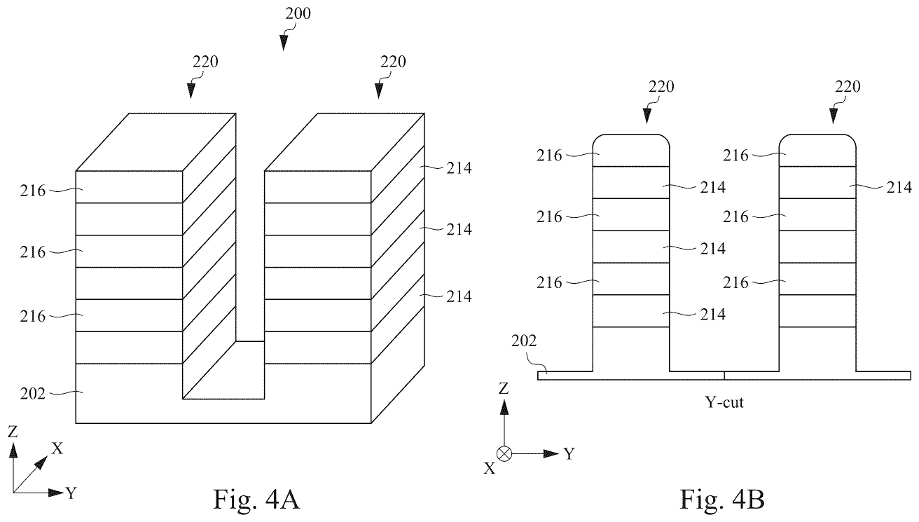

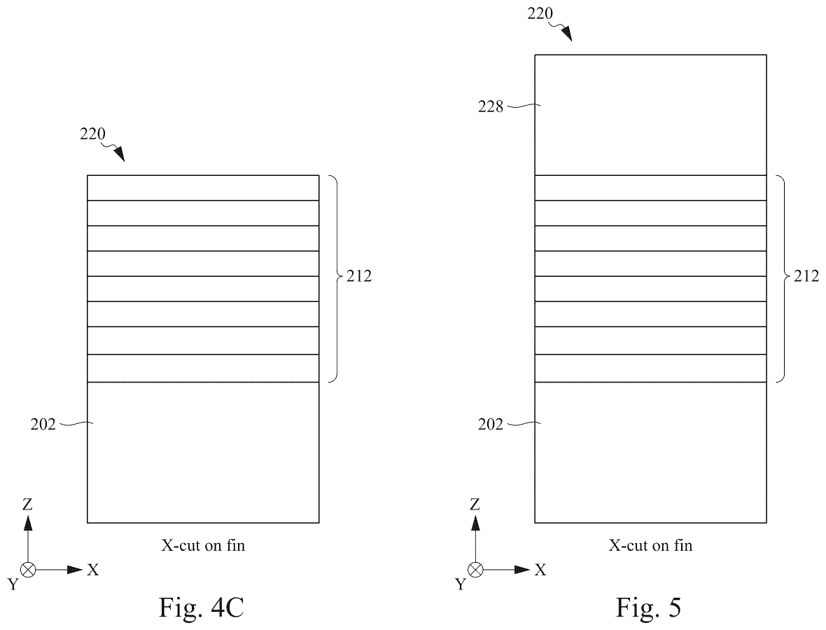

At block 106, the example method 100 includes patterning the epitaxial stack to form semiconductor fins (also referred to as fins). Referring to the example of FIGS. 4A, 4B, and 4C, in an embodiment of block 106, a plurality of fins 220 extending from the substrate 202 are formed. In various embodiments, each of the fins 220 includes an upper portion of the interleaved epitaxial layers 214 and 216 and a bottom portion protruding from the substrate 202.

The fins 220 may be fabricated using suitable processes including photolithography and etch processes. The photolithography process may include forming a photoresist layer over the substrate 202 (e.g., over the epitaxial stack 212), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate 202, and epitaxial stack 212 formed thereupon, while an etch process forms trenches in unprotected regions through masking layer(s) such as hard mask, thereby leaving the plurality of extending fins. The trenches may be etched using a dry etch (e.g., reactive ion etching), a wet etch, and/or other suitable processes. The trenches may be filled with dielectric material forming, for example, shallow trench isolation features interposing the fins.

At block 108, the example method 100 includes forming one or more sacrificial layers/features over the substrate. Referring to the example of FIG. 5, in an embodiment of block 108, a sacrificial gate dielectric layer (not shown) is blanket deposited over the fin 220, which is formed over the substrate 202. A sacrificial gate electrode layer 228 is then blanket deposited on the sacrificial gate dielectric layer and over the substrate 202. The sacrificial gate electrode layer 228 includes silicon such as polycrystalline silicon or amorphous silicon. The thickness of the sacrificial gate dielectric layer is in a range from about 1 nm to about 5 nm in some embodiments. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer 228 may be deposited using CVD, including LPCVD and PECVD, PVD, ALD, or other suitable processes.

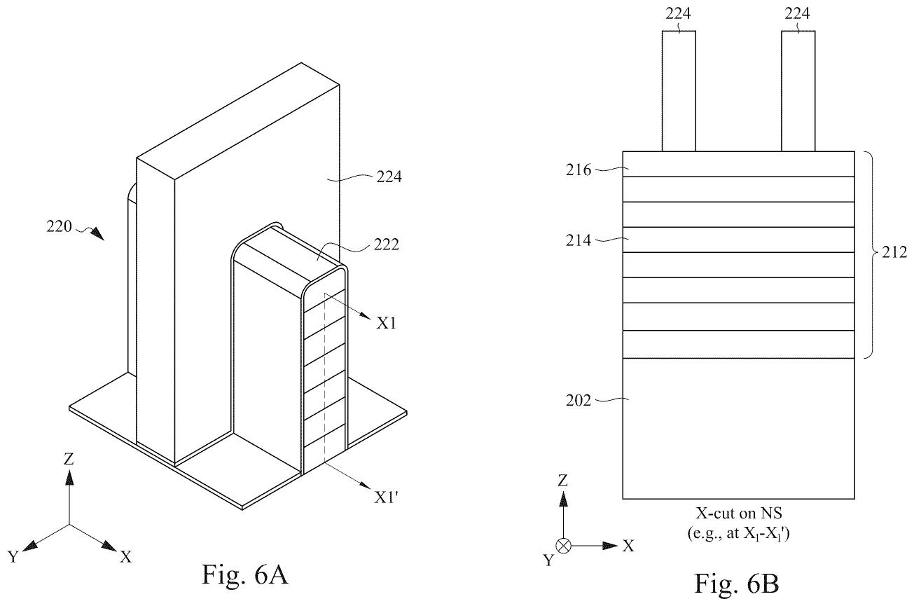

At block 110, the example method 100 includes patterning the one or more sacrificial layers/features to form a dummy gate structure on channel regions of the fins. Referring to the example of FIGS. 6A and 6B, in an embodiment of block 110, a sacrificial gate structure 224 is formed over portions of the fins 220 which are to be channel regions. The sacrificial gate structure 224 defines the channel regions of a GAA device. The sacrificial gate structure 224 includes a sacrificial gate dielectric layer and a sacrificial gate electrode layer 228. The sacrificial gate structure 224 is formed by forming a mask layer over the sacrificial gate electrode layer. The mask layer may include a pad silicon oxide layer and a silicon nitride mask layer. Subsequently, a patterning operation is performed on the mask layer and sacrificial gate dielectric and electrode layers are patterned into the sacrificial gate structure 224. By patterning the sacrificial gate structure 224, the fins 220 are partially exposed on opposite sides of the sacrificial gate structure 224, thereby defining source/drain (S/D) regions. In this disclosure, a source and a drain are interchangeably used, and the structures thereof are substantially the same.

The sacrificial gate structure 224 is subsequently removed as discussed with reference to block 132 of the method 100 and will be replaced by a final gate stack at a subsequent processing stage of the device 200. In particular, the sacrificial gate structure 224 is replaced at a later processing stage by a high-K dielectric layer (HK) and metal gate electrode (MG) as discussed below.

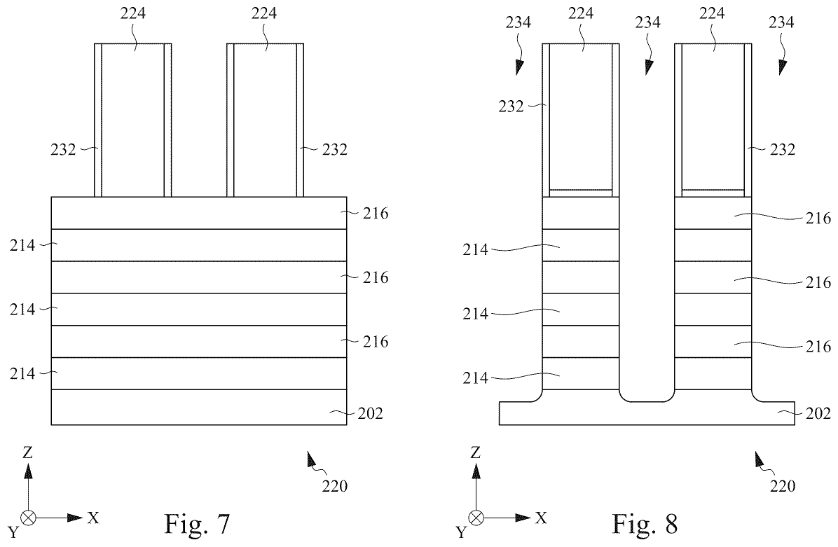

At block 112, the example method 100 includes forming gate sidewall spacers on sidewalls of the sacrificial gate structure. Referring to the example of FIG. 7, in an embodiment of block 112, gate sidewall spacers 232 are formed on sidewalls of the sacrificial gate structure 224. In various embodiments, the gate sidewall spacers 232 may include a dielectric material such as silicon oxide (SiOₓ), silicon nitride (SiN), silicon carbide (SiC), silicon oxynitride (SiON), SiCN films, silicon oxycarbide (SiOC), Silicon oxycarbonitride (SiOCN) films, and/or combinations thereof. In some embodiments, the gate sidewall spacers 232 include multiple layers, such as main spacer walls, liner layers, and the like. By way of example, the gate sidewall spacers 232 may be formed by depositing a dielectric material layer over the sacrificial gate structure 224 using processes such as, a CVD process, a sub atmospheric CVD (SACVD) process, a flowable CVD process, an ALD process, a PVD process, or other suitable process. In some embodiments, the deposition of the dielectric material layer is followed by an etching-back (e.g., anisotropically) process to expose portions of the fin 220 adjacent to and not covered by the sacrificial gate structure 224 (e.g., S/D regions). The dielectric material layer may remain on the sidewalls of the sacrificial gate structure 224 as gate sidewall spacers 232. In some embodiments, the etching-back process may include a wet etch process, a dry etch process, a multiple-step etch process, and/or a combination thereof. The gate sidewall spacers 232 may have a thickness ranging from about 5 nm to about 20 nm.

At block 114, the example method 100 optionally includes treating the gate sidewall spacers 232 to make the gate sidewall spacers 232 more resistant to Germanium (Ge) penetration during later fabrication operations, such as sacrificial gate removal and replacement gate fabrication operations. In various embodiments, treating the gate sidewall spacers 232 involves performing curing operations to cure and solidify the gate sidewall spacers 232. In various embodiments, the curing operations involve Ultra-Violet (UV) curing operations. In various embodiments, the UV curing operations involve exposing the gate sidewall spacers 232 to UV light while heated at a temperature between about 150° C. and 405° C. in the presence of helium, argon, or nitrogen. In various embodiments, the UV curing operations involve exposing the gate sidewall spacers 232 to UV light at a power of about 30W to about 80W for about 1.5 minutes to about 3 minutes. In various embodiments, treating the gate sidewall spacers 232 can cause the gate sidewall spacers 232 to become harder or more solid. In various embodiments, hardening the gate sidewall spacers 232 results in hardened gate sidewall spacers with a thickness reduction of about 5% to about 20%. In various embodiments, hardening the gate sidewall spacers 232 can provide device performance enhancements, such as lower leakage.

At block 116, the example method includes recessing the fins in the source drain/regions. Referring to the example of FIG. 8, in an embodiment of block 116, the fin 220 is recessed in the source drain/regions. The stacked epitaxial layers 214 and 216 are etched down at the S/D regions to form a recess 234. In various embodiments, the recessing is performed by a suitable etching process, such as a dry etching process, a wet etching process, or an RIE process. Dry etching may be implemented using an etchant including a bromine-containing gas (e.g., HBr and/or CHBR3), a fluorine-containing gas (e.g., CF4, SF6, CH2F2, CHF3, and/or C2F6), other suitable gases, or combinations thereof.

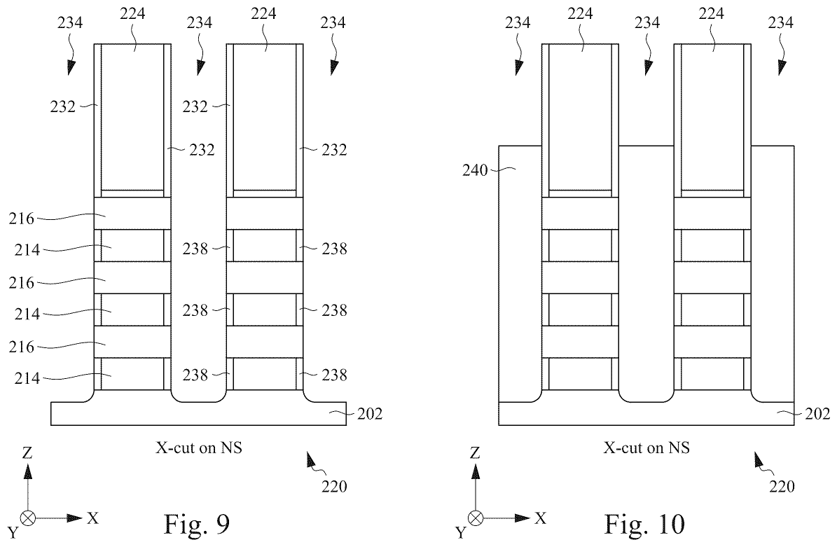

At block 118, the example method 100 Includes forming inner spacers. Forming inner spacers may include recessing sacrificial epitaxial layers (e.g., SiGe), depositing inner spacer material, and etching back inner spacer material. Referring to the example of FIG. 9, in an embodiment of block 118, inner spacers 238 are formed. The sacrificial epitaxial layers 214 have been etched back. The sacrificial epitaxial layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, at block 118 lateral ends of the sacrificial epitaxial layers 214 that are exposed in the recess 234 may be selectively oxidized to increase the etch selectivity between the epitaxial layers 214 and 216. In some examples, the oxidation process may be performed by exposing the device 200 to a wet oxidation process, a dry oxidation process, or a combination thereof.

The inner spacers 238 may include silicon oxides, silicon nitrides, silicon carbides, silicon carbide nitride, silicon oxide carbide, silicon carbide oxynitride, and/or other suitable dielectric materials. In some embodiments, the inner spacer material layer is deposited as a conformal layer. The inner spacer material layer can be formed by ALD or any other suitable method. After the inner spacer material layer is formed, an etching operation may be performed to partially remove the inner spacer material layer. In various embodiments, the inner spacers 238 are formed from the same material as the gate sidewall spacers 232. In various embodiments, the gate sidewall spacers 232 and the inner spacers 238 are formed from SiOCN.

At block 120, the example method 100 optionally includes treating the inner spacers 238 or both the gate sidewall spacers 232 and the inner spacers 238 to make the inner spacers 238 or both the gate sidewall spacers 232 and the inner spacers 238 more resistant to Germanium (Ge) penetration during later fabrication operations, such as sacrificial gate removal and replacement gate fabrication operations. In various embodiments, treating the inner spacers 238 or both the gate sidewall spacers 232 and the inner spacers 238 involves performing curing operations to cure and solidify the inner spacers 238 or both the gate sidewall spacers 232 and the inner spacers 238. In various embodiments, the curing operations involve Ultra-Violet (UV) curing operations. In various embodiments, the UV curing operations involve exposing the inner spacers 238 or both the gate sidewall spacers 232 and the inner spacers 238 to UV light while heated at a temperature between about 150° C. and 405° C. in the presence of helium, argon, or nitrogen. In various embodiments, the UV curing operations involve exposing the inner spacers 238 or both the gate sidewall spacers 232 and the inner spacers 238 to UV light at a power of about 30W to about 80W for about 1.5 minutes to about 3 minutes. In various embodiments, treating the inner spacers 238 or both the gate sidewall spacers 232 and the inner spacers 238 can cause the inner spacers 238 or both the gate sidewall spacers 232 and the inner spacers 238 to become harder or more solid. In various embodiments, hardening the inner spacers 238 or both the gate sidewall spacers 232 and the inner spacers 238 results in hardened spacers with a thickness reduction of about 5% to about 20%.

At block 122, the example method 100 includes forming source/drain (S/D) features. Referring to the example of FIG. 10, in an embodiment of block 122, epitaxial S/D features 240 are formed in recess 234. In some embodiments, the epitaxial S/D features 240 include silicon for NFETs and SiGe for PFETs. In some embodiments, the epitaxial S/D features 240 are formed by an epitaxial growth method using CVD, ALD, or molecular beam epitaxy (MBE). The epitaxial S/D features 240 are formed in contact with the channel epitaxial layers 216 and separated from the sacrificial epitaxial layers 214 by the inner spacers 238.

At block 124, the example method 100 includes forming a CESL layer. Referring to the example of FIG. 11, in an embodiment of block 124, a CESL layer 242 is formed over the S/D features 240. The CESL layer 242 may comprise silicon nitride, silicon oxynitride, silicon nitride with oxygen (O) or carbon (C) elements, and/or other materials; and may be formed by CVD, PVD (physical vapor deposition), ALD, or other suitable methods. In various embodiments, the CESL layer 242 is formed from SiN.

At block 126, the example method 100 optionally includes treating the CESL layer 242 to make the CESL layer 242 more resistant to Germanium (Ge) penetration during later fabrication operations, such as sacrificial gate removal and replacement gate fabrication operations. In various embodiments, treating the CESL layer 242 involves performing curing operations to cure and solidify the CESL layer 242. In various embodiments, the curing operations involves Ultra-Violet (UV) curing operations. In various embodiments, the UV curing operations involve exposing the CESL layer 242 to UV light while heated at a temperature between about 150° C. and 405° C. in the presence of helium, argon, or nitrogen. In various embodiments, the UV curing operations involve exposing the CESL layer 242 to UV light at a power of about 30W to about 80W for about 1.5 minutes to about 3 minutes. In various embodiments, treating the CESL layer 242 can cause the CESL layer 242 to become harder or more solid. In various embodiments, hardening the CESL layer 242 results in hardened CESL with a thickness reduction of about 5% to about 20%.

At block 128, the example method 100 includes forming an ILD layer. Referring to the example of FIG. 12, in an embodiment of block 128, an interlayer dielectric (ILD) layer 244 is formed over the CESL layer 242. The ILD layer 244 may comprise tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 244 may be formed by PECVD, flowable CVD (FCVD), or other suitable methods. In some embodiments, forming the ILD layer 244 further includes performing a CMP process to planarize a top surface of the device 200, such that the top surfaces of the sacrificial gate structure 224 are exposed.

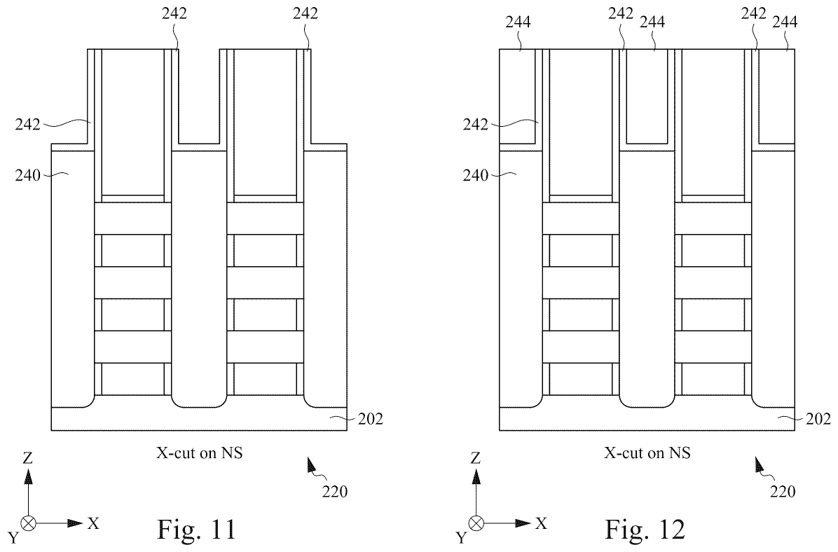

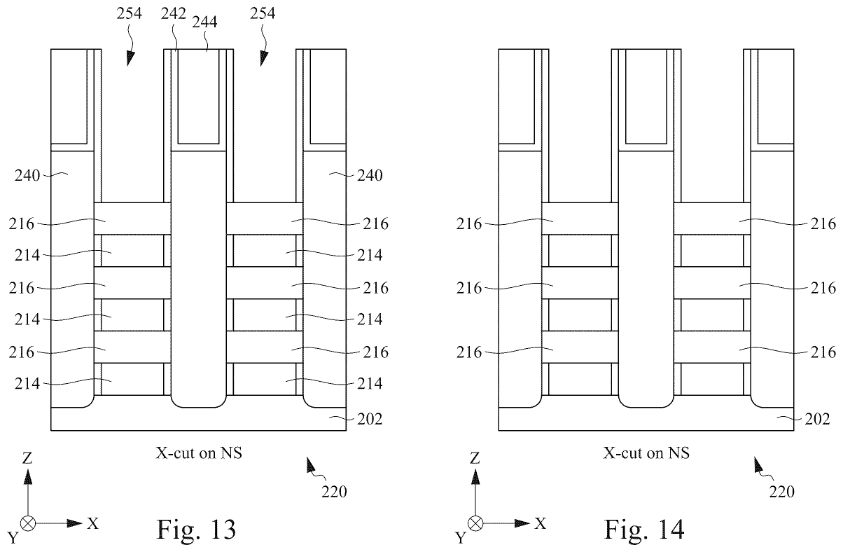

At block 130, the example method 100 includes removing the dummy gate stack to form a gate trench. Referring to the example of FIG. 13, in an embodiment of block 130, the sacrificial gate structure 224 has been removed to form a gate trench 254. The gate trench 254 exposes the fin 220 in the channel region(s). The ILD layer 244 and the CESL layer 242 protects the epitaxial S/D features 240 during the removal of the sacrificial gate structure 224. The sacrificial gate structure 224 can be removed using plasma dry etching and/or wet etching. When the sacrificial gate electrode layer is polysilicon and the ILD layer 244 is an oxide, a wet etchant such as a TMAH solution can be used to selectively remove the sacrificial gate electrode layer. The sacrificial gate dielectric layer is thereafter removed using plasma dry etching and/or wet etching.

At block 132, the example method 100 includes removing the sacrificial epitaxial layers to form nanosheets. Referring to the example of FIG. 14, in an embodiment of block 132, sacrificial epitaxial layers 214 have been removed thereby releasing channel members from the channel region of the GAA device. In the illustrated embodiment, channel members are channel epitaxial layers 216 in the form of nanosheets. In various embodiments, the channel epitaxial layers 216 include silicon, and the sacrificial epitaxial layers 214 include silicon germanium. In various embodiments, the plurality of sacrificial epitaxial layers 214 were selectively removed via a selective removal process that included oxidizing the plurality of sacrificial epitaxial layers 214 using a suitable oxidizer, such as ozone. Thereafter, the oxidized sacrificial epitaxial layers 214 were selectively removed via a dry etching process, for example, by applying an HCl gas at a temperature of about 500 degrees Celsius to about 700 degrees Celsius, or applying a gas mixture of CF₄, SF₆, and CHF₃.

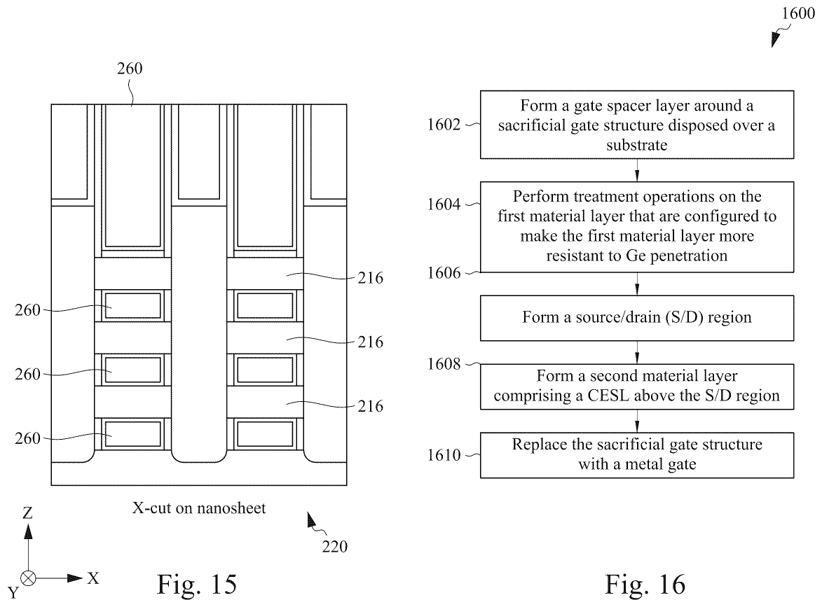

At block 134, the example method 100 includes forming high-K metal gate structures. Referring to the example of FIG. 15, in an embodiment of block 134, a gate structure 260 is formed. In various embodiments, the gate structure is the gate of a multi-gate transistor. In various embodiments, the gate structure is a high-K metal gate stack, however other compositions are possible. In various embodiments the high-K metal gate stack includes a gate dielectric layer that includes an interfacial layer and a high-k dielectric layer. The high-k dielectric layer wraps each of the nanosheets 216, and the interfacial layer is interposed between the high-k dielectric layer and the nanosheets 216. The interfacial layer may include a dielectric material such as silicon oxide (SiO₂) or silicon oxynitride (SiON), and may be formed by chemical oxidation, thermal oxidation, atomic layer deposition (ALD), CVD, and/or other suitable methods. The high-k dielectric layer may include hafnium oxide (HfO₂), hafnium silicon oxide (HfSiO), hafnium silicon oxynitride (HfSiON), hafnium tantalum oxide (HMO), hafnium titanium oxide (HfTiO), hafnium zirconium oxide (HfZrO), other suitable high-k dielectric materials, and/or combinations thereof. The high-k material may further be selected from metal oxides, metal nitrides, metal silicates, transition metal-oxides, transition metal-nitrides, transition metal-silicates, oxynitrides of metals, metal aluminates, zirconium silicate, zirconium aluminate, silicon oxide, silicon nitride, silicon oxynitride, zirconium oxide, titanium oxide, aluminum oxide, hafnium dioxide-alumina (HfO₂—Al₂O₃) alloy, other suitable materials, and/or combinations thereof. The high-k dielectric layer may be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof. In one embodiment, the gate dielectric layer is formed using a highly conformal deposition process such as ALD in order to ensure the formation of a gate dielectric layer having a uniform thickness around each channel layers. The high-K metal gate structures may include additional material layers.

At block 136, the example method 100 includes performing further fabrication. A semiconductor device may undergo further processing to form various features and regions known in the art. For example, subsequent processing may form contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 100, and some process steps described above may be replaced or eliminated in accordance with various embodiments of the method 100.

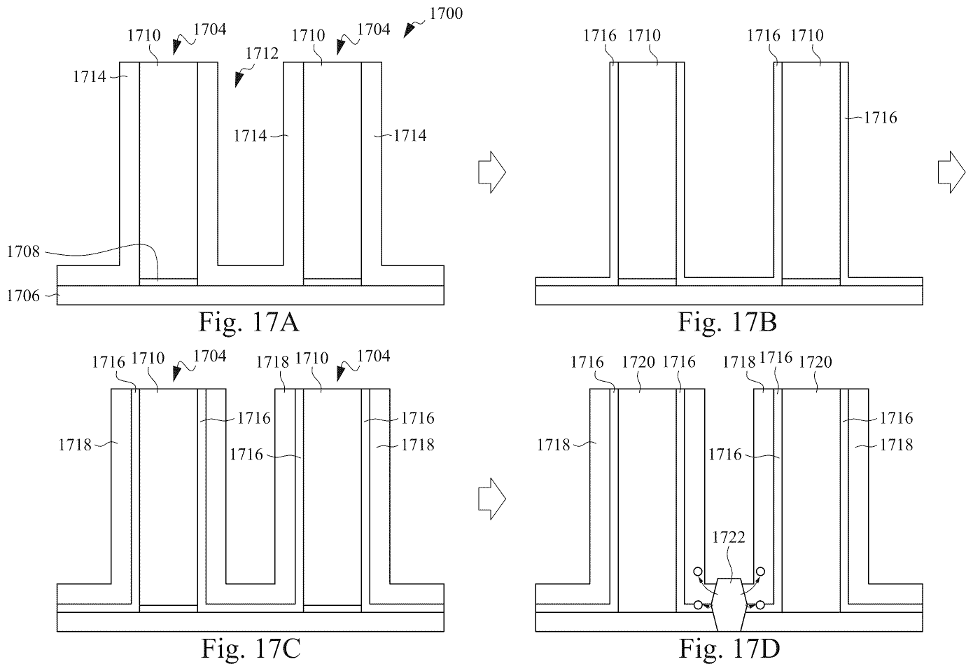

FIG. 16 is a flow chart depicting an example method 1600 of semiconductor fabrication, according to various aspects of the present disclosure. FIG. 16 is described in conjunction with FIGS. 17A-17D, which are schematic diagrams that illustrate an example FinFET device 1700 at various stages of fabrication, in accordance with some embodiments. In some figures, some reference numbers of components or features illustrated therein may be omitted to avoid obscuring other components or features; this is for ease of depicting the figures. The method 1600 is merely an example and is not intended to limit the present disclosure beyond what is explicitly recited in the claims. Additional steps may be provided before, during, and after method 1600, and some of the steps described can be moved, replaced, or eliminated for additional embodiments of method 1600. Additional features may be added in the FinFET device 1700 depicted in the figures, and some of the features described below can be replaced, modified, or eliminated in other embodiments.

As with the other method embodiments and exemplary devices discussed herein, it is understood that parts of the FinFET device 1700 may be fabricated by semiconductor technology process flow, and thus some processes are only briefly described herein. Moreover, it is noted that the process steps of method 1600, include any descriptions given with reference to the figures, as with the remainder of the method and exemplary figures provided in this disclosure, are merely exemplary and are not intended to be limiting beyond what is specifically recited in the claims that follow.

At operation 1602, the example method 1600 includes forming a gate spacer layer around a sacrificial gate structure disposed over a substrate. Referring to the example of FIG. 17A, in an embodiment of operation 1602, a plurality of sacrificial gate structures 1704 are disposed over a Fin 1706 on a substrate (not shown). The sacrificial gate structures 1704 include a dielectric layer 1708 and a poly layer 1710. A first material layer 1712 comprising a gate spacer layer 1714 is disposed around the sacrificial gate structures 1704.

At operation 1604, the example method 1600 includes performing treatment operations on the first material layer (including the spacer layer) that are configured to make the first material layer more resistant to Germanium (Ge) diffusion during metal gate replacement operations. In various embodiments, performing the treatment operations on the first material layer comprises performing curing operations configured to make the first material layer harder. In various embodiments, performing curing operations configured to make the first material layer harder comprises exposing the first material layer to UV light while heated. In various embodiments, exposing the first material layer to UV light while heated comprises exposing the first material layer to UV light while heated at a temperature between about 150° C. and 405° C. in the presence of helium, argon, or nitrogen. In various embodiments, exposing the first material layer to UV light while heated includes exposing the first material layer to UV light at a power of about 30W to about 80W for about 1.5 minutes to about 3 minutes. Referring to the example of FIG. 17B, in an embodiment of operation 1604, the first material layer 1712 (including the gate spacer layer 1714) has been cured via UV light to produce a hardened first material layer 1716. In various embodiments, the thickness of the hardened first material layer 1716 has been reduced by about 5% to about 20% from the thickness of the first material layer 1712.

In various embodiments, the hardened first material layer 1716 comprises SiOCN and has a higher concentration of C after curing operations than the first material layer 1712. In various embodiments the concentration of C in the hardened first material layer 1716 increases by approximately 3% over the concentration of C in the first material layer 1712. In various embodiments, the first material layer 1712 may have a C concentration of 11.37% and the hardened first material layer 1716 may have a C concentration of 14.26%. In various embodiments, the increase in C concentration may occur due to a decrease in oxygen (O) concentration. In various embodiments, the increase in C concentration causes the hardened first material layer 1716 to be harder than the first material layer 1712 and more resistant to Ge diffusion.

In various embodiments, the hardened first material layer 1716 has a higher concentration of N after curing operations. In various embodiments the concentration of N in the hardened first material layer 1716 increases by approximately 4% over the concentration of N in the first material layer 1712. In various embodiments, the increase in N concentration may occur due to a decrease in O concentration. In various embodiments, the increase in N concentration causes the hardened first material layer 1716 to be harder than the first material layer 1712 and more resistant to Ge diffusion.

In various embodiments, the hardened first material layer 1716 forms a channel protective layer that protects the metal gates 1720 from Ge penetration during metal gate formation. In various embodiments, the protective layer may be formed from UV Curing, Plasma treatment, and e-beam therapy.

In various embodiments, the FinFET device 1700 may be a GAA FinFET device. When the FinFET device 1700 is a GAA FinFET device, the first material layer may further comprise inner gate spacers (not shown) and the inner gate spacers may likewise have curing operations performed thereon.

At operation 1606, the example method 1600 includes forming a source/drain (S/D) region and, at operation 1608, forming a second material layer comprising a contact etch stop layer (CESL) adjacent to the first material layer 1712 and above the S/D region. Referring to the example of FIG. 17C, in an embodiment of operation 1608, a second material layer 1718 comprising a CESL is formed adjacent to the first material layer 1712 and above the S/D region (e.g., in area between the two depicted sacrificial gate structures 1704).

At operation 1610, the example method 1600 includes replacing the sacrificial gate structure with a metal gate. Referring to the example of FIG. 17D, in an embodiment of operation 1610, the sacrificial gate structures 1704 have been replaced with metal gates 1720. Also, as illustrated, Ge 1722 (e.g., from the S/D regions and/or sacrificial epitaxial layers) is blocked from entering the metal gate 1720 by the hardened first material layer 1716, for example, during metal gate replacement operations. Blocking the Ge 1722 can improve device performance, such as lower voltage peak deviation, due to lower leakage. In various embodiments, the Ge 1722 is diffused into the hardened first material layer 1716 and the second material layer 1718 but not into the metal gates 1720. In various embodiments, the Ge 1722 can be detected in the hardened first material layer 1716 and the second material layer 1718 near the S/D regions and/or sacrificial epitaxial layers, but not near the top of the hardened first material layer 1716 or near the top of the second material layer 1718. In various embodiments, the concentration of Ge 1722 in the hardened first material layer 1716 and the second material layer 1718 is gradient with a higher concentration in a bottom portion near the S/D regions and/or sacrificial epitaxial layers, but zero concentration near the top portion of the hardened first material layer 1716 or near the top portion of the second material layer 1718. The Ge 1722 does not chemically bond to either the hardened first material layer 1716 or the second material layer 1718.

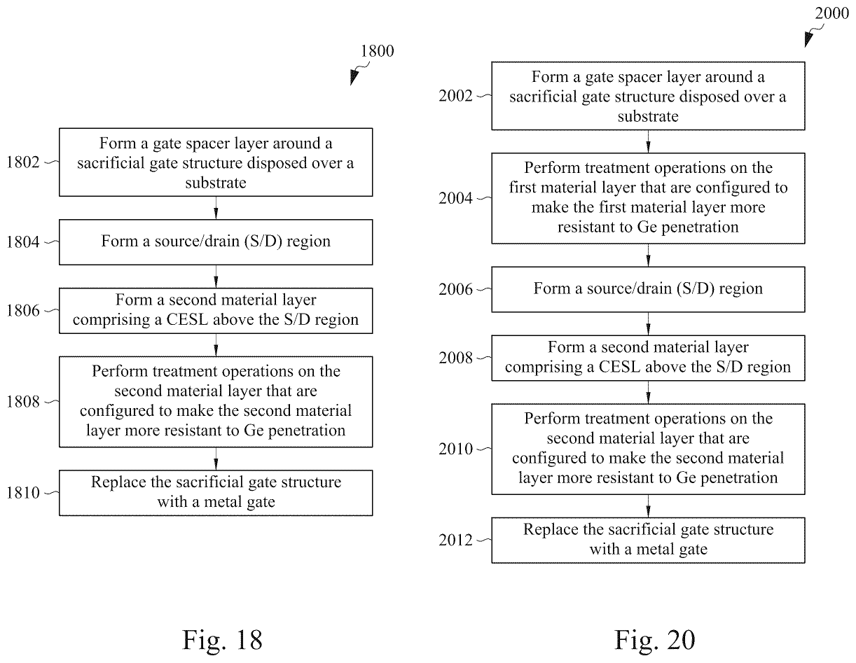

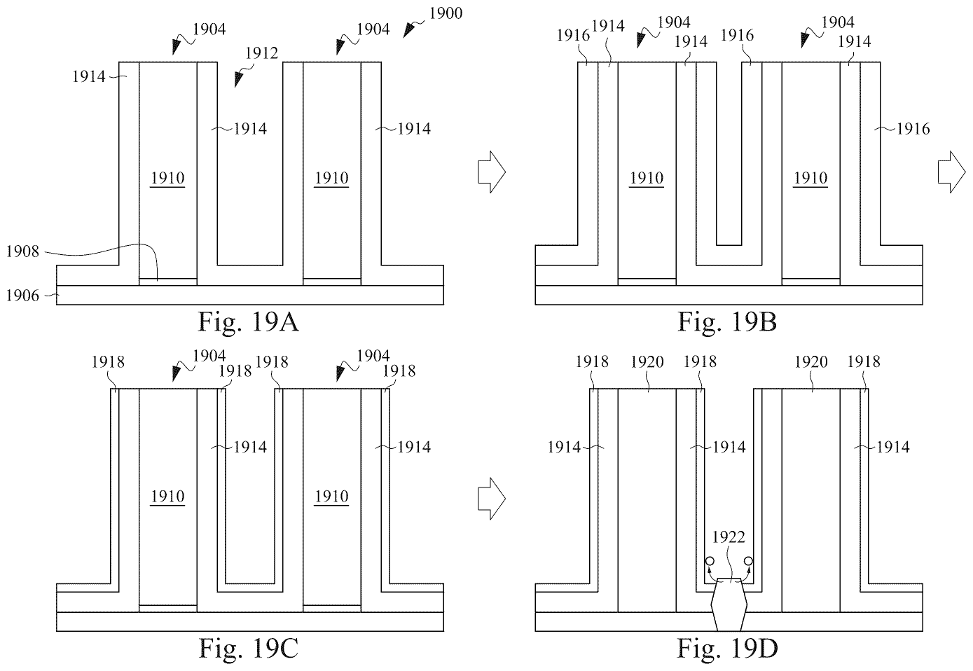

FIG. 18 is a flow chart depicting an example method 1800 of semiconductor fabrication, according to various aspects of the present disclosure. FIG. 18 is described in conjunction with FIGS. 19A-19D, which are schematic diagrams that illustrate an example FinFET device 1900 at various stages of fabrication, in accordance with some embodiments. In some figures, some reference numbers of components or features illustrated therein may be omitted to avoid obscuring other components or features; this is for ease of depicting the figures. The method 1800 is merely an example and is not intended to limit the present disclosure beyond what is explicitly recited in the claims. Additional steps may be provided before, during, and after method 1800, and some of the steps described can be moved, replaced, or eliminated for additional embodiments of method 1800. Additional features may be added in the FinFET device 1900 depicted in the figures, and some of the features described below can be replaced, modified, or eliminated in other embodiments.

As with the other method embodiments and exemplary devices discussed herein, it is understood that parts of the FinFET device 1900 may be fabricated by semiconductor technology process flow, and thus some processes are only briefly described herein. Moreover, it is noted that the process steps of method 1800, include any descriptions given with reference to the figures, as with the remainder of the method and exemplary figures provided in this disclosure, are merely exemplary and are not intended to be limiting beyond what is specifically recited in the claims that follow.

At operation 1802, the example method 1800 includes forming a gate spacer layer around a sacrificial gate structure disposed over a substrate. Referring to the example of FIG. 19A, in an embodiment of operation 1802, a plurality of sacrificial gate structures 1904 are disposed over a Fin 1906 on a substrate (not shown). The sacrificial gate structures 1904 include a dielectric layer 1908 and a poly layer 1910. A first material layer 1912 comprising a gate spacer layer 1914 is disposed around the sacrificial gate structures 1904.

At operation 1804, the example method 1800 includes forming a source/drain (S/D) region and, at operation 1806, forming a second material layer comprising a contact etch stop layer (CESL) adjacent to the first material layer 1912 and above the S/D region. Referring to the example of FIG. 19B, in an embodiment of operation 1806, a second material layer 1916 comprising a CESL is formed adjacent to the first material layer 1912 and above the S/D region (e.g., in area between the two depicted sacrificial gate structures 1904).

At operation 1808, the example method 1800 includes performing treatment operations on the second material layer that are configured to make the second material layer more resistant to Germanium (Ge) penetration during metal gate replacement operations. In various embodiments, performing the treatment operations on the second material layer comprises performing curing operations configured to make the second material layer become harder or more solid. In various embodiments, performing curing operations configured to make the second material layer become harder comprises exposing the second material layer to UV light while heated. In various embodiments, exposing the second material layer to UV light while heated comprises, exposing the second material layer to UV light while heated at a temperature between about 150° C. and 405° C. in the presence of helium, argon, or nitrogen. In various embodiments, exposing the second material layer to UV light while heated involves exposing the second material layer to UV light at a power of about 30W to about 80W for about 1.5 minutes to about 3 minutes. Referring to the example of FIG. 19C, in an embodiment of operation 1808, the second material layer 1916 has been cured via UV light to produce a hardened second material layer 1918. In various embodiments, the thickness of the hardened second material layer 1918 has been reduced by about 5% to about 20% from the thickness of the second material layer 1916.

In various embodiments, the hardened second material layer 1918 comprises SiN and has a higher concentration of N after curing operations. In various embodiments the concentration of N in the hardened second material layer 1918 increases by approximately 4% over the concentration of N in the second material layer 1916. In various embodiments, the increase in N concentration may occur due to a decrease in Si concentration. In various embodiments, the increase in N concentration causes the hardened second material layer 1918 to be harder than the second material layer 1916 and more resistant to Ge diffusion.

In various embodiments, the hardened second material layer 1918 forms a channel protective layer that protects the metal gates 1920 from Ge penetration during metal gate formation. In various embodiments, the protective layer may be formed from UV Curing, Plasma treatment, and e-beam therapy.

At operation 1810, the example method 1800 includes replacing the sacrificial gate structure with a metal gate. Referring to the example of FIG. 19D, in an embodiment of operation 1810, the sacrificial gate structures 1904 have been replaced with metal gates 1920. Also, as illustrated, Ge 1922 (e.g., from the S/D regions and/or sacrificial epitaxial layers) is blocked from entering the metal gate 1920 by the hardened second material layer 1918, for example, during metal gate replacement operations. Blocking the Ge can improve device performance, such as lower voltage peak deviation, due to lower leakage. In various embodiments, at EPI region, the G% is >=(1E20), and the Ge% at the middle of the MG-to-EPI is less than 1% of the Ge% at the SiGe edge.

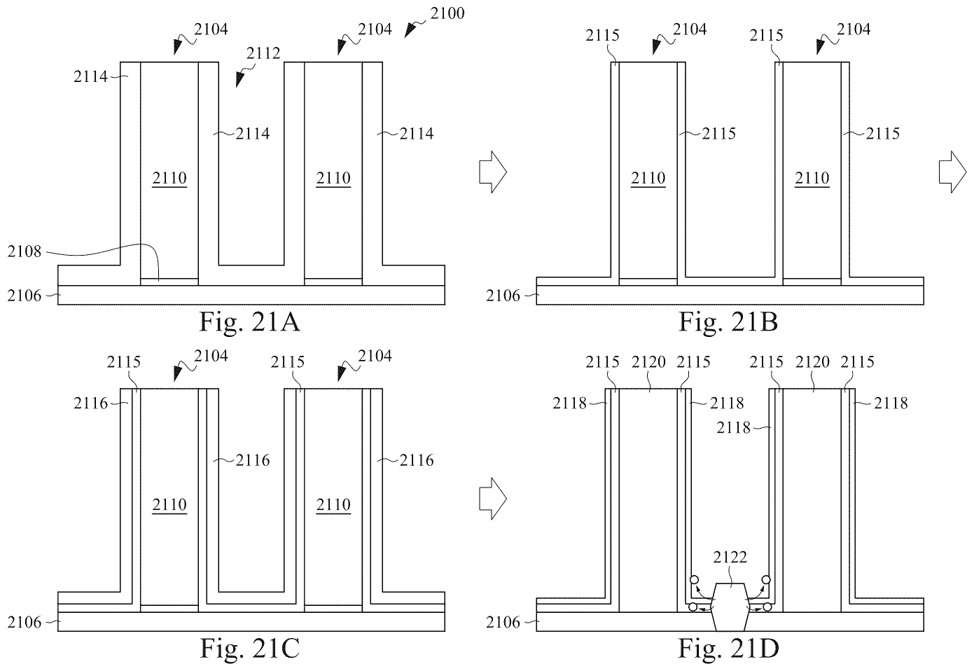

FIG. 20 is a flow chart depicting an example method 2000 of semiconductor fabrication, according to various aspects of the present disclosure. FIG. 20 is described in conjunction with FIGS. 21A-21D, which are schematic diagrams that illustrate an example FinFET device 2100 at various stages of fabrication, in accordance with some embodiments. In some figures, some reference numbers of components or features illustrated therein may be omitted to avoid obscuring other components or features; this is for ease of depicting the figures. The method 2000 is merely an example and is not intended to limit the present disclosure beyond what is explicitly recited in the claims. Additional steps may be provided before, during, and after method 2000, and some of the steps described can be moved, replaced, or eliminated for additional embodiments of method 2000. Additional features may be added in the FinFET device 2100 depicted in the figures, and some of the features described below can be replaced, modified, or eliminated in other embodiments.

As with the other method embodiments and exemplary devices discussed herein, it is understood that parts of the FinFET device 2100 may be fabricated by semiconductor technology process flow, and thus some processes are only briefly described herein. Moreover, it is noted that the process steps of method 2000, include any descriptions given with reference to the figures, as with the remainder of the method and exemplary figures provided in this disclosure, are merely exemplary and are not intended to be limiting beyond what is specifically recited in the claims that follow.

At operation 2002, the example method 2000 includes forming a gate spacer layer around a sacrificial gate structure disposed over a substrate. Referring to the example of FIG. 21A, in an embodiment of operation 2002, a plurality of sacrificial gate structures 2104 are disposed over a Fin 2106 on a substrate (not shown). The sacrificial gate structures 2104 include a dielectric layer 2108 and a poly layer 2110. A first material layer 2112 comprising a gate spacer layer 2114 is disposed around the sacrificial gate structures 2104. In various embodiments, the first material layer comprises silicon oxycarbonitride (SiOCN).

At operation 2004, the example method 2000 includes performing treatment operations on the first material layer (including the spacer layer) that are configured to make the first material layer more resistant to Germanium (Ge) penetration during metal gate replacement operations. In various embodiments, performing the treatment operations on the first material layer comprises performing curing operations configured to make the first material layer become harder or more solid. In various embodiments, performing curing operations configured to make the first material layer become harder comprises exposing the first material layer to UV light while heated. In various embodiments, exposing the first material layer to UV light while heated comprises exposing the first material layer to UV light while heated at a temperature between about 150° C. and 405° C. in the presence of helium, argon, or nitrogen. In various embodiments, exposing the first material layer to UV light while heated includes exposing the first material layer to UV light at a power of about 30W to about 80W for about 1.5 minutes to about 3 minutes. Referring to the example of FIG. 21B, in an embodiment of operation 2004, the first material layer 2112 (including the gate spacer layer 2114) has been cured via UV light to produce a hardened first material layer 2115. In various embodiments, hardening the first material layer results in a hardened first material layer 2112 with a thickness reduction of about 5% to about 20%.

In various embodiments, the hardened first material layer 2115 comprises SiOCN and has a higher concentration of C after curing operations than the first material layer 2112. In various embodiments the concentration of C in the hardened first material layer 2115 increases by approximately 3% over the concentration of C in the first material layer 2112. In various embodiments, the first material layer 2112 may have a C concentration of 11.37% and the hardened first material layer 2115 may have a C concentration of 14.26%. In various embodiments, the increase in C concentration may occur due to a decrease in O concentration. In various embodiments, the increase in C concentration causes the hardened first material layer 1716 to be harder than the first material layer 1712 and more resistant to Ge diffusion.

In various embodiments, the hardened first material layer 2115 has a higher concentration of N after curing operations. In various embodiments the concentration of N in the hardened first material layer 2115 increases by approximately 4% over the concentration of N in the first material layer 2112. In various embodiments, the increase in N concentration may occur due to a decrease in Si concentration. In various embodiments, the increase in N concentration causes the hardened first material layer 2115 to be harder than the first material layer 2112 and more resistant to Ge diffusion.

In various embodiments, the FinFET device 2100 may be a GAA FinFET device. When the FinFET device 2100 is a GAA FinFET device, the first material layer may further comprise inner gate spacers (not shown) and the inner gate spacers may likewise have curing operations performed thereon.

At operation 2006, the example method 2000 includes forming a source/drain (S/D) region and, at operation 2008, forming a second material layer comprising a contact etch stop layer (CESL) adjacent to the first material layer 2112 and above the S/D region. Referring to the example of FIG. 21C, in an embodiment of operation 2008, a second material layer 2116 comprising a CESL is formed adjacent to the first material layer 2112 and above the S/D region (e.g., in area between the two depicted sacrificial gate structures 2104).

At operation 2010, the example method 2000 includes performing treatment operations on the second material layer that are configured to make the second material layer more resistant to Germanium (Ge) penetration during metal gate replacement operations. In various embodiments, performing the treatment operations on the second material layer comprises performing curing operations configured to make the second material layer become harder or more solid. In various embodiments, performing curing operations configured to harden the second material layer comprises exposing the second material layer to UV light while heated. In various embodiments, exposing the second material layer to UV light while heated comprises, exposing the second material layer to UV light while heated at a temperature between about 150° C. and 405° C. in the presence of helium, argon, or nitrogen. In various embodiments, exposing the second material layer to UV light while heated includes exposing the second material layer to UV light at a power of about 30W to about 80W for about 1.5 minutes to about 3 minutes. Referring to the example of FIG. 21D, in an embodiment of operation 2008, the second material layer 2116 has been cured via UV light to produce a hardened second material layer 2118. In various embodiments, hardening the second material layer results in a hardened second material layer 2118 with a thickness reduction of about 5% to about 20%.

In various embodiments, the hardened second material layer 2118 comprises SiN and has a higher concentration of N after curing operations. In various embodiments, the increase in N concentration may occur due to a decrease in Si concentration. In various embodiments, the increase in N concentration causes the hardened second material layer 1918 to be harder than the first material layer 1912 and more resistant to Ge diffusion.

In various embodiments, the hardened first material layer 2115 and the hardened second material layer 2118 form a channel protective layer that protects the metal gates 2120 from Ge penetration during metal gate formation. In various embodiments, the protective layer may be formed from UV Curing, Plasma treatment, and e-beam therapy.

At operation 2012, the example method 2000 includes replacing the sacrificial gate structure with a metal gate. Referring to the example of FIG. 21D, in an embodiment of operation 2012, the sacrificial gate structures 2104 have been replaced with metal gates 2120. Also, as illustrated, Ge 2122 (e.g., from the S/D regions and/or sacrificial epitaxial layers) is blocked from entering the metal gate 2120 by the hardened first material layer 2115 and the hardened second material layer 2118 during metal gate replacement operations. Blocking the Ge can improve device performance, such as lower voltage peak deviation, due to lower leakage.

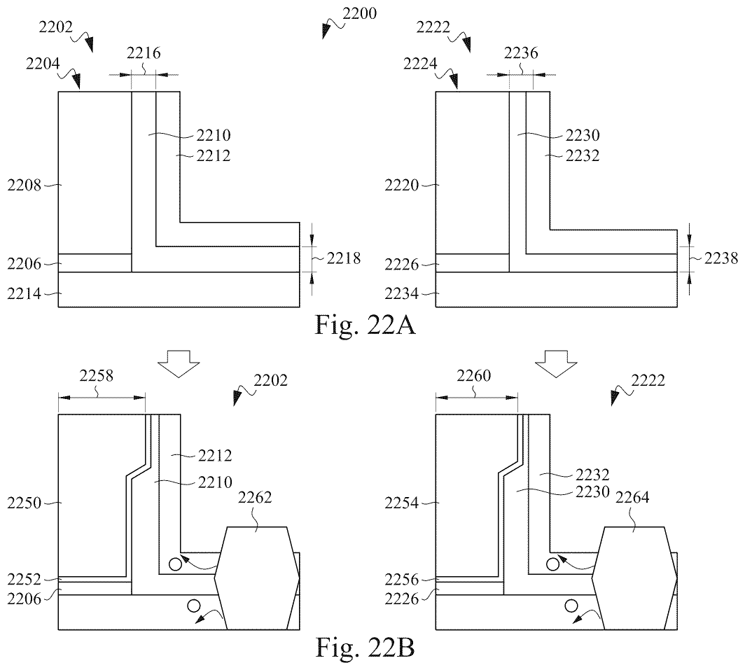

FIGS. 22A and 22B are schematic diagrams that illustrate a semiconductor structure 2200 having a first transistor 2202 and a second transistor 2222 at different fabrication stages, in accordance with some embodiments. FIG. 22A is a schematic diagram that illustrates the semiconductor structure 2200 at a first fabrication stage, in accordance with some embodiments. FIG. 22B is a schematic diagram that illustrates the semiconductor structure 2200 at a second fabrication stage, in accordance with some embodiments.

The first transistor 2202, at the first fabrication stage, includes a first sacrificial gate structure 2204 comprising a first dielectric 2206 and a first poly silicon region 2208. The first transistor 2202 further includes a first hardened gate spacer 2210 (e.g., formed of SiOCN) that has been cured by UV light, and a first ESL 2212 (e.g., formed of SiN). The first transistor 2202 is formed over a fin 2214. The first hardened gate spacer 2210 has a first sidewall thickness 2216 and a first top thickness 2218.

The second transistor 2222, at the first fabrication stage, includes a second sacrificial gate structure 2224 comprising a second dielectric 2226 and a second poly silicon region 2228. The second transistor 2222 further includes a second hardened gate spacer 2230 (e.g., formed of SiOCN) that has been cured by UV light, and a second ESL 2232 (e.g., formed of SiN). The second transistor 2222 is formed over a fin 2234. The second hardened gate spacer 2230 has a second sidewall thickness 2236 and a second top thickness 2238.

The UV curing has resulted in the first sidewall thickness 2216 of the first hardened gate spacer 2210 being greater than the second sidewall thickness 2236 of the second hardened gate spacer 2230. Also, the first top thickness 2218 of the first hardened gate spacer 2210 is greater than or equal to the second top thickness 2238 of the second hardened gate spacer 2230.

FIG. 22B is a schematic diagram that illustrates the semiconductor structure 2200 after poly silicon removal and metal gate replacement operations, in accordance with some embodiments. The first transistor 2202 after metal gate replacement operations includes a first metal gate 2250 and a first hi-K gate dielectric layer 2252, and the second transistor 2222 after metal gate replacement operations includes a second metal gate 2254 and a second hi-K gate dielectric layer 2256. The first hardened gate spacer 2210 and the second hardened gate spacer 2230 are resistant to Ge diffusion (from Ge 2262 and Ge 2264) and protect the first metal gate 2250 and the second metal gate 2254 from Ge penetration during metal gate replacement operations. Because the first sidewall thickness 2216 is greater than the second sidewall thickness 2236, the first metal gate 2250 can be made larger than the second metal gate 2254. More of the sidewall of the first hardened gate spacer 2210 can be etched away during poly silicon removal operations than the sidewall of the second hardened gate spacer 2230. In various embodiments, the first metal gate 2250 has a first thickness 2258 near the top of the first metal gate 2250 that is greater than a second thickness 2260 near the top of the second metal gate 2254.

Improved systems, fabrication methods, fabrication techniques, and articles have been described. The described systems, methods, techniques, and articles can be used with a wide range of semiconductor devices including FinFET, Gate-all-around FET (GAAFET / NSFET), Fork-sheet, CFET, VFET, MOSFET, 2D material device, planer device, BEOL device, NAND, 3D NAND, NMOS or PMOS.

In some aspects, the techniques described herein relate to a fabrication method, including: forming a gate spacer layer around a sacrificial gate structure disposed over a substrate; performing, on a first material layer including the gate spacer layer, treatment operations that are configured to make the first material layer more resistant to Germanium (Ge) diffusion during metal gate replacement operations; forming a second material layer adjacent to the first material layer; and replacing the sacrificial gate structure with a metal gate, wherein the first material layer blocks Ge from entering the metal gate.

In some aspects, the techniques described herein relate to a method, wherein performing the treatment operations on the first material layer includes performing curing operations configured to make the material layer become harder.

In some aspects, the techniques described herein relate to a method, wherein performing curing operations configured to harden the first material layer includes exposing the first material layer to UV light while heated.

In some aspects, the techniques described herein relate to a method, wherein the first material layer further includes inner gate spacers.

In some aspects, the techniques described herein relate to a method, wherein the first material layer includes silicon oxycarbonitride (SiOCN) and has a greater carbon concentration level after treatment operations are performed.

In some aspects, the techniques described herein relate to a method, further including performing treatment operations on the second material layer that are configured to make the second material layer more resistant to Ge diffusion during metal gate replacement operations.

In some aspects, the techniques described herein relate to a method, wherein the second material layer includes silicon nitride (SiN) and has a greater nitrogen concentration level after treatment operations are performed.

In some aspects, the techniques described herein relate to a semiconductor structure, including: a metal gate structure; a source region and a drain region, a first material layer formed around the metal gate structure with Ge diffused in a bottom portion of the first material layer near a source/drain region but not near a top portion of the first material layer, wherein the Ge is not bonded to the first material layer, wherein the Ge is not bonded to the first material layer; and a second material layer disposed adjacent to the first material layer.

In some aspects, the techniques described herein relate to a semiconductor structure, wherein the second material layer includes a second material layer that has Ge diffused in a bottom portion of the first material layer near the source/drain region but not near a top portion of the first material layer, wherein the Ge is not bonded to the first material layer.

In some aspects, the techniques described herein relate to a semiconductor structure, wherein the first material layer includes silicon oxycarbonitride (SiOCN) and the second material layer includes silicon nitride (SiN).

In some aspects, the techniques described herein relate to a semiconductor structure, wherein the first material layer includes a gate spacer layer.

In some aspects, the techniques described herein relate to a semiconductor structure, wherein the first material layer further includes an inner gate spacer layer disposed between the source/drain region and metal gate structures formed around nanosheets.

In some aspects, the techniques described herein relate to a semiconductor structure, wherein the metal gate structure is disposed over a channel region of a FinFET device.

In some aspects, the techniques described herein relate to a semiconductor structure, wherein the metal gate structure is disposed over a channel region of a GAA FinFET device.

In some aspects, the techniques described herein relate to a semiconductor structure, wherein the metal gate structure is disposed over a channel region of a planar MOSFET device.

In some aspects, the techniques described herein relate to a fabrication method, including: performing curing operations configured to harden a first material layer including a spacer layer formed around a sacrificial gate structure; removing the sacrificial gate structure; forming a metal gate to replace the sacrificial gate structure; and blocking, via the first material layer, Geranium (Ge) from entering the metal gate while forming the metal gate.

In some aspects, the techniques described herein relate to a method, further including forming source/drain (S/D) features wherein the S/D features includes SiGe, and blocking the Ge from entering the metal gate includes blocking Ge from the SiGe in the S/D features from entering the metal gate.

In some aspects, the techniques described herein relate to a method, wherein removing the sacrificial gate structure includes removing sacrificial epitaxial layers from an epitaxial stack, the first material layer further includes inner gate spacers disposed between source/drain (S/D) features and the epitaxial stack, and blocking the Ge from entering the metal gate includes blocking Ge from SiGe in the sacrificial epitaxial layers from entering the metal gate.

In some aspects, the techniques described herein relate to a method, wherein performing curing operations includes exposing the first material layer to UV light while heated.

In some aspects, the techniques described herein relate to a method, further including forming a second material layer adjacent to the first material layer, performing curing operations configured to make the second material layer become harder, and blocking, via the second material layer, Geranium (Ge) from entering the metal gate while forming the metal gate.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A method, comprising:
forming a gate spacer layer around a sacrificial gate structure disposed over a substrate;
performing, on a first material layer comprising the gate spacer layer, treatment operations that are configured to make the first material layer more resistant to Germanium (Ge) diffusion during metal gate replacement operations;
forming a second material layer adjacent to the first material layer; and
replacing the sacrificial gate structure with a metal gate, wherein the first material layer blocks Ge from entering the metal gate.

2. The method of claim 1, wherein performing the treatment operations on the first material layer comprises performing curing operations configured to make the first material layer become harder.

3. The method of claim 2, wherein performing curing operations configured to harden the first material layer comprises exposing the first material layer to UV light while heated.

4. The method of claim 1, wherein the first material layer further comprises inner gate spacers.

5. The method of claim 1, wherein the first material layer comprises silicon oxycarbonitride (SiOCN) and has a greater carbon concentration level after treatment operations are performed.

6. The method of claim 1, further comprising performing treatment operations on the second material layer that are configured to make the second material layer more resistant to Ge diffusion during metal gate replacement operations.

7. The method of claim 6, wherein the second material layer comprises silicon nitride (SiN) and has a greater nitrogen concentration level after treatment operations are performed.

8. A semiconductor structure, comprising:
a metal gate structure;
a first material layer formed around the metal gate structure with Ge diffused in a bottom portion of the first material layer near a source/drain region but not near a top portion of the first material layer, wherein the Ge is not bonded to the first material layer; and
a second material layer disposed adjacent to the first material layer.

9. The semiconductor structure of claim 8, wherein the second material layer has Ge diffused in a bottom portion of the second material layer near the source/drain region but not near a top portion of the second material layer, wherein the Ge is not bonded to the second material layer.

10. The semiconductor structure of claim 8, wherein the first material layer comprises silicon oxycarbonitride (SiOCN) and the second material layer comprises silicon nitride (SiN).

11. The semiconductor structure of claim 8, wherein the first material layer comprises a gate spacer layer.

12. The semiconductor structure of claim 11, wherein the first material layer further comprises an inner gate spacer layer disposed between the source/drain region and metal gate structures formed around nanosheets.

13. The semiconductor structure of claim 8, wherein the metal gate structure is disposed over a channel region of a FinFET device.

14. The semiconductor structure of claim 8, wherein the metal gate structure is disposed over a channel region of a GAA FinFET device.

15. The semiconductor structure of claim 8, wherein the metal gate structure is disposed over a channel region of a planar MOSFET device.

16. A method, comprising:
performing curing operations configured to make a first material layer comprising a spacer layer formed around a sacrificial gate structure become harder;
removing the sacrificial gate structure;
forming a metal gate to replace the sacrificial gate structure; and
blocking, via the first material layer, Geranium (Ge) from entering the metal gate while forming the metal gate.

17. The method of claim 16, further comprising forming source/drain (S/D) features wherein the S/D features comprises SiGe, and blocking the Ge from entering the metal gate comprises blocking Ge from the SiGe in the S/D features from entering the metal gate.

18. The method of claim 16, wherein removing the sacrificial gate structure comprises removing sacrificial epitaxial layers from an epitaxial stack, the first material layer further comprises inner gate spacers disposed between source/drain (S/D) features and the epitaxial stack, and blocking the Ge from entering the metal gate comprises blocking Ge from SiGe in the sacrificial epitaxial layers from entering the metal gate.

19. The method of claim 16, wherein performing curing operations comprises exposing the first material layer to UV light while heated.

20. The method of claim 16, further comprising forming a second material layer adjacent to the first material layer, performing curing operations configured to make the second material layer become harder, and blocking, via the second material layer, Geranium (Ge) from entering the metal gate while forming the metal gate.
